(19) United States
(12) Patent Application Publication
(10) Pub. No.: US 2019/0386149 A1
(43) Pub. Date: Dec. 19, 2019

(54) BACK-CHANNEL-ETCH TYPE OXIDE SEMICONDUCTOR TFT SUBSTRATE AND FABRICATING METHODS THEREOF

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventors: Mingjue YU, Shenzhen, Guangdong (CN); Yuanjun HSU, Shenzhen, Guangdong (CN); Xingyu ZHOU, Shenzhen, Guangdong (CN)

(21) Appl. No.: 15/742,772

(22) PCT Filed: Nov. 29, 2017
(86) PCT No.: PCT/CN2017/113547

§ 371 Date: Jan. 8, 2018

(30) Foreign Application Priority Data
Oct. 25, 2017 (CN) 201711010218.5

(51) Int. Cl. H01L 29/786; H01L 27/12; H01L 29/66

(52) U.S. Cl. CPC H01L 29/78696; H01L 27/1225; H01L 21/44; H01L 29/66969; H01L 29/7869

(57) ABSTRACT

The disclosure provides a back-channel-etch type oxide semiconductor TFT substrate and fabricating method thereof. The method configures an active layer as a double layer structure, and a first oxide semiconductor layer located in a lower layer is prepared according to normal deposition process parameters and has normal density and a second oxide semiconductor layer located in an upper layer is prepared by changing deposition process parameters and has higher density; the first oxide semiconductor layer has lower density and higher mobility and the second oxide semiconductor layer has higher density, fewer numbers of film defects, more strong etch resistance, it is capable of reducing damage of a channel region of an active layer during the process for etching a drain electrode and a source electrode, and at the same time saves a mask for a etch stop layer, cuts down the fabricating cost.

### RELATED APPLICATIONS

The present application is a National Phase of International Application Number PCT/CN2017/113547, filed on Nov. 29, 2017, and claims the priority of China Application 201711010218.5, filed on Oct. 25, 2017.

### FIELD OF THE DISCLOSURE

The disclosure relates to the field of display technology, and particularly to a back-channel-etch type oxide semiconductor TFT substrate and fabricating methods thereof.

### BACKGROUND

A liquid crystal display (LCD) is widely used as, for example, a mobile phone, a personal digital assistant (PDA), a digital camera, a desktop computer screen or a notebook computer screen and so on for its numerous merits such as thin body, power saving and radiationless.

An organic light-emitting diode (OLED) display, also known as an organic electroluminescence display, is an emerging panel display device and has a broad prospect of application due to its merits such as simple manufacturing process, low cost, low power consumption, high luminance, wide range of operating temperature, light and thin volume, quick response speed, realizable color display and large screen display, realizable matching with drivers for integrated circuits, and realizable flexible display.

OLED can be classified into two kinds according to driving modes, passive matrix OLED (PMOLED) and active matrix OLED (AMOLED), namely direct addressing and thin film transistor matrix addressing. Among them, AMOLED has pixels arranged in an array, belonging to the active display type, high luminous efficiency and is usually used for large-size display devices having high definition.

Thin film transistors (be short for TFTs) are major driving elements in current liquid crystal displays and active matrix OLED display devices and directly related to development indirection of high performance panel display devices. Thin film transistors have varieties of structures and there are also many kinds of materials for preparation thin film transistors having the corresponding structures, and amorphous silicon (a-Si) material is one of relatively common materials.

With the development of liquid crystal display devices and OLED display devices toward large size and high resolution, the traditional a-Si having only mobility of about 1 cm²/(Vs) is already unable to satisfy the requirement, and indium gallium zinc oxide (IGZO) as the representative for metal oxides has mobility over 10 cm²/(Vs), and the preparation of the corresponding thin film transistors has good compatibility with the existing production line, wherein a-Si is used for driving semiconductors, and has quickly become a key point of research and development in the field of display in recent years.

Compared with the traditional a-Si TFTs, IGZO TFTs have the following advantages.

1. Resolution of display backing plate is increased, and on the premise that the same transmittance is guaranteed, the resolution of display backing plate of IGZO TFT may be 2 times more than a-Si TFTs, and IGZO materials have high carrier concentration and large mobility, and the volume of TFTs may be reduced, thereby ensuring that the resolution is improved.

2. The energy consumption of the display device is reduced, and compared with a-Si TFT and LTPS TFT, for IGZO TFT, the leakage current is less than 1 pA; driving frequency is reduced from the original 30-50 Hz to 2-5 Hz, and even can reach 1 Hz through the special process; although reduced driving times of TFTs, the alignment of the liquid crystal molecules can still be maintained without affecting the quality of pictures, so as to reduce the power consumption of the display backing plate; In addition, high mobility of IGZO semiconductor materials enables TFTs having smaller size to provide sufficient charging capacity and higher capacitance, and improve aperture ratio of liquid crystal panels, enlarge active area of light penetration, and the same luminance may be attained by using less backing plate assemblies or low power consumption, thereby reducing energy consumption.

3. The influence of the noise of driving circuits for liquid crystal displays on detection circuits for touch screens can be reduced by adopting intermittent driving mode and the like, and the higher sensitivity can be achieved, and even the pointed tip of ball pens can make a response, and since a picture is not updated, the electric source can be cut off, and thus its effect on energy saving is even better.

At present, IGZO as TFT of a semiconductor active layer generally adopts an etch stop (ESL) structure. Due to the presence of the etch stop Layer, during etching a source/drain, the etch stop layer can effectively protect the IGZO active layer from being affected, so as to ensure that TFTs have excellent semiconductor properties. However, the preparation process of IGZO TFT with the ESL structure is relatively complicated and requires 6 times of yellow light processes, it is unfavorable to reducing the cost. Therefore, there is a general trend to develop IGZO TFT with a back-channel-etch (BCE) structure and with less yellow light processes in the industry.

Since IGZO TFTs with the BCE structure fail to configure the etch stop layer therein to shield the back channel, the channel region of the IGZO active layer is easily damaged during the process for etching source/drain, and due to more numbers of film defects in the IGZO active layer, the IGZO TFT is sensitive to the environment, and performances of TFT are easily affected by light, water vapor (H₂O), oxygen (O₂), hydrogen (H₂) and organics and so on in the environment, thereby resulting in lower reliability of TFT devices and reduced service life of panels.

### SUMMARY

The purpose of the disclosure is to provide a method for fabricating back-channel-etch type oxide semiconductor TFT substrate, it is capable of reducing damage of a channel region of an active layer during the process for etching a drain electrode and a source electrode so that the number of film defects in an active layer can be effectively decreased, and at the same time saves a mask for a etch stop layer, cuts down the fabricating cost.

The purpose of the disclosure is also to provide a back-channel-etch type oxide semiconductor TFT substrate, and its active layer has not only higher mobility, but also fewer numbers of film defects, and TFT devices are less affected by environment, thereby having higher reliability.

In order to achieve the above purposes, the disclosure provides a method for fabricating a back-channel-etch type oxide semiconductor TFT substrate, including:

providing a substrate, depositing and etching a metal material on the substrate to form a gate electrode, and forming a gate insulation layer on the substrate for covering the gate electrode;

depositing a first oxide semiconductor layer on the gate insulation layer, depositing a second oxide semiconductor layer on the first oxide semiconductor layer, and a density of the second oxide semiconductor layer being greater than a density of the first oxide semiconductor layer;

patterning the first oxide semiconductor layer and the second oxide semiconductor layer to obtain an active layer;

depositing and etching a metal material on the active layer and the gate insulation layer to form a drain electrode and a source electrode, and the drain electrode and the source electrode contacting with two sides of the active layer, respectively;

forming a passivation layer on the gate insulation layer for covering the drain electrode, the source electrode and the active layer; forming a through-hole on the passivation layer and corresponding to a part over the drain electrode.

Materials for the first oxide semiconductor layer and the second oxide semiconductor layer include one or more of indium gallium zinc oxide and indium zinc tin oxide, respectively; the materials for the first oxide semiconductor layer and the second oxide semiconductor layer are the same or different.

The density of the first oxide semiconductor layer is less than 6.4 g/cm³, and the density of the second oxide semiconductor layer is greater than 6.4 g/cm³.

A thickness of the first oxide semiconductor layer is greater than a thickness of the second oxide semiconductor layer.

A material for the gate electrode includes one or more of molybdenum, aluminum, and copper; the gate insulation layer is a silicon nitride layer, a silicon oxide layer, or a lamination composite film of the silicon nitride layer and the silicon oxide layer; the passivation layer is a silicon nitride layer or a silicon oxide layer; materials for the drain electrode and the source electrode include one or more of molybdenum, aluminum, and copper.

The disclosure also provides a back-channel-etch type oxide semiconductor TFT substrate, including; a the substrate, a gate electrode disposed on the substrate, a gate insulation layer disposed on the substrate and covering the gate electrode, an active layer disposed on the gate insulation layer and corresponding to a part over the gate electrode, a drain electrode and a source electrode disposed on the active layer and the gate insulation layer and contacted with two sides of the active layer respectively, a passivation layer disposed on the gate insulation layer and covering the drain electrode, the source electrode and the active layer, and a through-hole disposed on the passivation layer and corresponding to the part over the drain electrode;

the active layer includes a first oxide semiconductor layer disposed on the gate insulation layer and a second oxide semiconductor layer disposed on the first oxide semiconductor layer, and a density of the second oxide semiconductor layer is greater than a density of the first oxide semiconductor layer.

Materials for the first oxide semiconductor layer and the second oxide semiconductor layer include one or more of indium gallium zinc oxide and indium zinc tin oxide, respectively; the materials for the first oxide semiconductor layer and the second oxide semiconductor layer are the same or different.

The density of the first oxide semiconductor layer is less than 6.4 g/cm³, and the density of the second oxide semiconductor layer is greater than 6.4 g/cm³.

A thickness of the first oxide semiconductor layer is greater than a thickness of the second oxide semiconductor layer.

A material for the gate electrode includes one or more of molybdenum, aluminum, and copper; the gate insulation layer is a silicon nitride layer, a silicon oxide layer, or a lamination composite film of the silicon nitride layer and the silicon oxide layer; the passivation layer is a silicon nitride layer or a silicon oxide layer; materials for the drain electrode and the source electrode include one or more of molybdenum, aluminum, and copper.

The disclosure also provides a method for fabricating a back-channel-etch type oxide semiconductor TFT substrate, including:

providing a substrate, depositing and etching a metal material on the substrate to form a gate electrode, and forming a gate insulation layer on the substrate for covering the gate electrode;

depositing a first oxide semiconductor layer on the gate insulation layer, depositing a second oxide semiconductor layer on the first oxide semiconductor layer, and a density of the second oxide semiconductor layer being greater than a density of the first oxide semiconductor layer;

patterning the first oxide semiconductor layer and the second oxide semiconductor layer to obtain an active layer;

depositing and etching a metal material on the active layer and the gate insulation layer to form a drain electrode and a source electrode, and the drain electrode and the source electrode contacting with two sides of the active layer, respectively;

forming a passivation layer on the gate insulation layer for covering the drain electrode, the source electrode and the active layer; forming a through-hole on the passivation layer and corresponding to a part over the drain electrode;

wherein, materials for the first oxide semiconductor layer and the second oxide semiconductor layer include one or more of indium gallium zinc oxide and indium zinc tin oxide, respectively; the materials for the first oxide semiconductor layer and the second oxide semiconductor layer are the same or different;

wherein, the density of the first oxide semiconductor layer is less than 6.4 g/cm³, and the density of the second oxide semiconductor layer is greater than 6.4 g/cm³;

wherein, a thickness of the first oxide semiconductor layer is greater than a thickness of the second oxide semiconductor layer;

wherein, a material for the gate electrode includes one or more of molybdenum, aluminum, and copper; the gate insulation layer is a silicon nitride layer, a silicon oxide layer, or a lamination composite film of the silicon nitride layer and the silicon oxide layer; the passivation layer is a silicon nitride layer or a silicon oxide layer; materials for the drain electrode and the source electrode include one or more of molybdenum, aluminum, and copper.

The advantageous effects of the disclosure; the method for fabricating the back-channel-etch type oxide semiconductor TFT substrate of the disclosure configures an active layer as a double layer structure, and a first oxide semiconductor layer located in a lower layer is prepared according to normal deposition process parameters and has normal density and a second oxide semiconductor layer located in an upper layer is prepared by changing deposition process parameters and has higher density; the first oxide semiconductor layer has lower density and higher mobility and the second oxide semiconductor layer has higher density, fewer numbers of film defects, more strong etch resistance, it is capable of reducing damage of a channel region of an active layer during the process for etching a drain electrode and a source electrode, and at the same time saves a mask for a etch stop layer, cuts down the fabricating cost; therefore, the active layer of the back-channel-etch type oxide semiconductor TFT substrate prepared by the disclosure has not only higher mobility, but also fewer numbers of film defects, and TFT devices are less affected by light, moisture, oxygen, hydrogen and organics in the environment, thereby having higher reliability.

In order to further understand the features and technical contents of the disclosure, the following detailed descriptions and appended drawings of the disclosure are hereby referred. However, the appended drawings are merely provided for reference and illustration, without any intention to be used for limiting the disclosure.

### BRIEF DESCRIPTION OF THE DRAWINGS

The technical solution and other advantageous effects will become apparent by the detailed description of the specific embodiments of the disclosure in conjunction with the appended drawings.

FIG. 1 is a flow chart of a method for fabricating a back-channel-etch type oxide semiconductor TFT substrate of the disclosure;

FIG. 2 is a schematic view of step S1 in the method for fabricating a back-channel-etch type oxide semiconductor TFT substrate of the disclosure;

FIG. 3 and FIG. 4 are schematic views of step S2 in the method for fabricating a back-channel-etch type oxide semiconductor TFT substrate of the disclosure;

FIG. 5 is a schematic view of step S3 in the method for fabricating a back-channel-etch type oxide semiconductor TFT substrate of the disclosure;

FIG. 6 and FIG. 7 are schematic views of step S4 in the method for fabricating a back-channel-etch type oxide semiconductor TFT substrate of the disclosure and FIG. 7 is a structural schematic view of a back-channel-etch type oxide semiconductor TFT substrate of the disclosure.

### DETAILED DESCRIPTION OF PREFERRED EMBODIMENTS

In order to further illustrate the technical means used in the disclosure and the effect thereof, the description is made below in detail in combination with the preferred embodiments of the disclosure and the appended drawings.

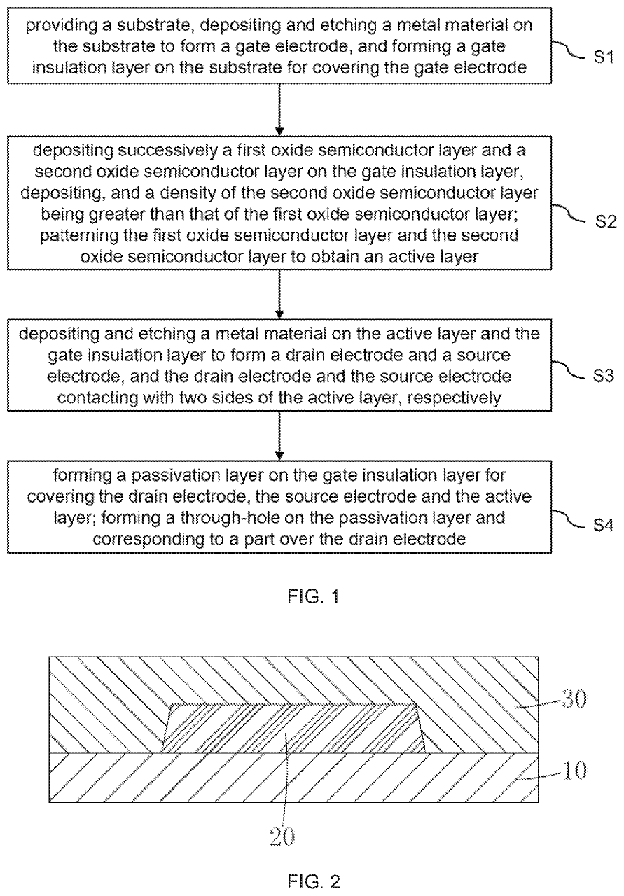

With reference to FIG. 1, the disclosure provides a method for fabricating a back-channel-etch type oxide semiconductor TFT substrate, including the following steps.

Step S1: as shown in FIG. 2, a substrate 10 is provide, and a metal material is deposited on the substrate 10 and etched to form a gate electrode 20, and a gate insulation layer 30 for covering the gate electrode 20 is formed on the substrate 10.

Specifically, the substrate 10 is a glass substrate.

Specifically, the step S1 further includes: washing and baking the substrate 10 before forming the gate electrode 20 on the substrate 10.

Specifically, a material for the gate electrode 20 includes one or more of molybdenum (Mo), aluminum (Al) and copper (Cu).

Specifically, the gate insulation layer 30 is a silicon nitride (SiNₓ) layer, a silicon oxide (SiOₓ) layer, or a lamination composite film of the silicon nitride (SiNₓ) layer and the silicon oxide (SiOₓ) layer.

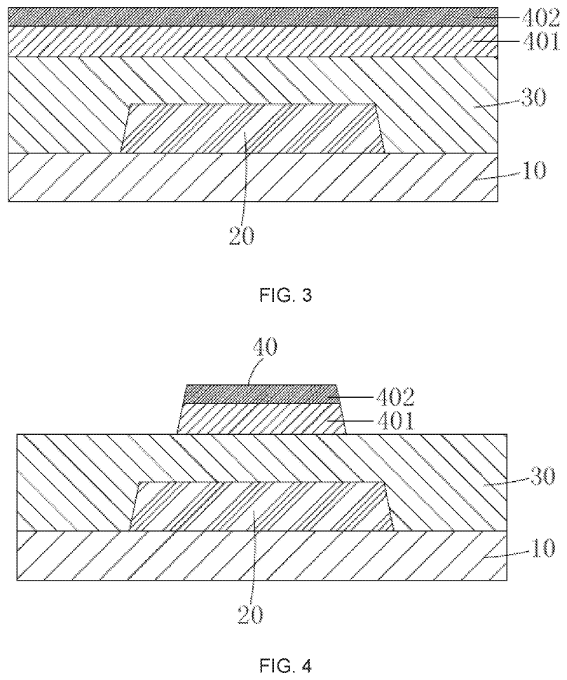

Step S2: as shown in FIG. 3, a first oxide semiconductor layer 401 is deposited on the gate insulation layer 30, and a second oxide semiconductor layer 402 is deposited on the first oxide semiconductor layer 401, and a density of the second oxide semiconductor layer 402 is greater than a density of the first oxide semiconductor layer 401;

as shown in FIG. 4, the first oxide semiconductor layer 401 and the second oxide semiconductor layer 402 are patterned to obtain an active layer 40.

Specifically, materials for the first oxide semiconductor layer 401 and the second oxide semiconductor layer 402 include one or more of indium gallium zinc oxide (IGZO) and indium zinc tin oxide (IZTO), respectively; the materials for the first oxide semiconductor layer 401 and the second oxide semiconductor layer 402 are the same or different.

Specifically, the density of the first oxide semiconductor layer 401 is less than 6.4 g/cm³, and the density of the second oxide semiconductor layer 402 is greater than 6.4 g/cm³.

Specifically, the first oxide semiconductor layer 401 is prepared according to normal deposition process parameters and has normal density and the second oxide semiconductor layer 402 is prepared by changing deposition process parameters and has higher density; in the disclosure, the first oxide semiconductor layer 401 can be configured to possess lower density so that its higher mobility can be guaranteed; the second oxide semiconductor layer 402 can be configured to possess higher density so that it has fewer numbers of film defects, and its relatively strong etch resistance can be ensured, and damages of a channel region 41 of the active layer 40 are effectively reduced during a subsequent process for etching a drain electrode 51 and a source electrode 52.

Preferably, the first oxide semiconductor layer 401 has a larger thickness, and the second oxide semiconductor layer 402 has a smaller thickness, namely the thickness of the first oxide semiconductor layer 401 is greater than the thickness of the second oxide semiconductor layer 402, thereby ensuring that the active layer 40 has higher mobility.

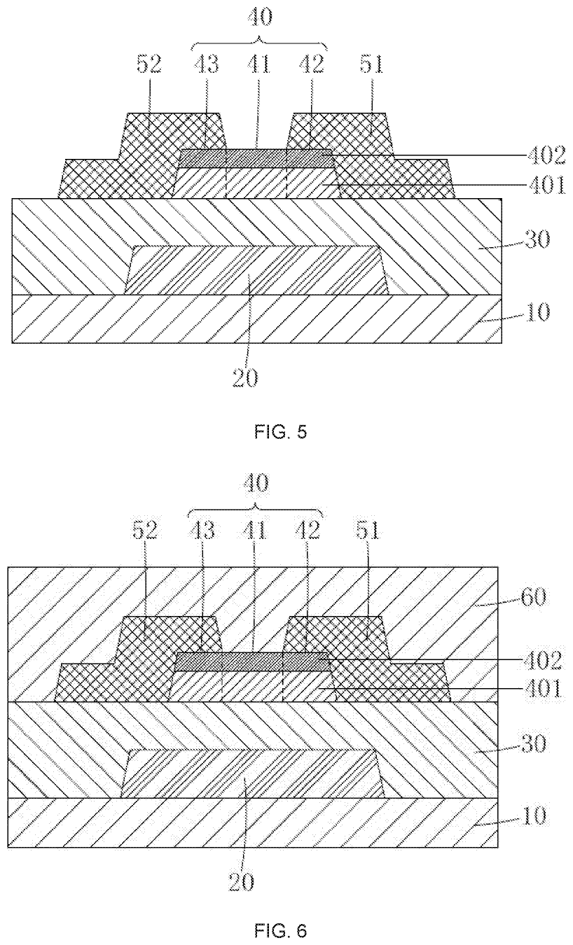

Step S3: as shown in FIG. 5, metal materials are deposited on the active layer 40 and the gate insulation layer 30 and etched to form the drain electrode 51 and the source electrode 52, and the drain electrode 51 and the source electrode 52 come into contact with two sides of the active layer 40, respectively.

Specifically, materials for the drain electrode 51 and the source electrode 52 include one or more of molybdenum (Mo), aluminum (Al), and copper(Cu).

Specifically, the drain electrode 51 and the source electrode 52 define the channel region 41 located between the drain electrode 51 and the source electrode 52, a drain electrode contact region 42 located at one side of the channel region 41 and contacted with the drain electrode 51, and a source electrode contact region 43 located at the other side of the channel region 41 and contacted with the source electrode 52 on the active layer 40.

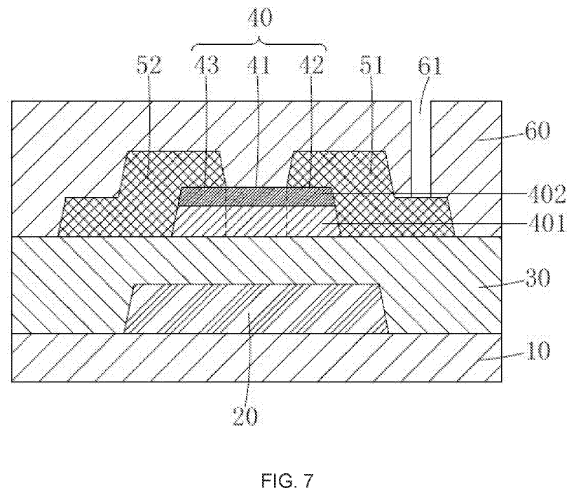

Step S4: as shown in FIG. 6, a passivation layer 60 is formed on the gate insulation layer 30 for covering the drain electrode 51, the source electrode 52 and the active layer 40; as shown in FIG. 7, a through-hole 61 is formed on the passivation layer 60, corresponding to a part over the drain electrode 51.

Specifically, the passivation layer 60 is a silicon nitride (SiNₓ) layer or a silicon oxide (SiOₓ) layer.

Specifically, electrical connection between a pixel electrode of LCD or an anode of OLED and the drain electrode 51 can be achieved by using the through-hole 61 during the subsequent process.

It is worth mentioning that the dotted lines in FIG. 5 to FIG. 7 are only used to delimit the channel region 41, the drain electrode contact region 42 and the source electrode contact region 43 of the active layer 40 and have no other meanings.

The method for fabricating the back-channel-etch type oxide semiconductor TFT substrate of the disclosure configures the active layer 40 as a double layer structure, and the first oxide semiconductor layer 401 located in the lower layer is prepared according to normal deposition process parameters and has normal density and the second oxide semiconductor layer 402 located in the upper layer is prepared by changing deposition process parameters and has higher density: the first oxide semiconductor layer 401 has lower density and higher mobility and the second oxide semiconductor layer 402 has higher density, fewer numbers of film defects, more strong etch resistance, it is capable of reducing damage of the channel region 41 of the active layer 40 during the process for etching the drain electrode 51 and the source electrode 52, and at the same time saves a mask for a etch stop layer and cuts down the fabricating cost; therefore, the active layer 40 of the back-channel-etch type oxide semiconductor TFT substrate prepared by the disclosure has not only higher mobility, but also fewer numbers of film defects, and TFT devices are less affected by light, moisture, oxygen, hydrogen and organics in the environment, thereby having higher reliability.

With reference to FIG. 7, based on the above method for fabricating the back-channel-etch type oxide semiconductor TFT substrate, the disclosure provides a back-channel-etch type oxide semiconductor TFT substrate, including: the substrate 10, the gate electrode 20 disposed on the substrate 10, the gate insulation layer 30 disposed on the substrate 10 and covering the gate electrode 20, the active layer 40 disposed on the gate insulation layer 30 and corresponding to a part over the gate electrode 20, the drain electrode 51 and the source electrode 52 disposed on the active layer 40 and the gate insulation layer 30 and contacted with two sides of the active layer 40 respectively, the passivation layer 60 disposed on the gate insulation layer 30 and covering the drain electrode 51, the source electrode 52 and the active layer 40, and the through-hole 61 disposed on the passivation layer 60 and corresponding to the part over the drain electrode 51;

the active layer 40 includes the first oxide semiconductor layer 401 disposed on the gate insulation layer 30 and the second oxide semiconductor layer 402 disposed on the first oxide semiconductor layer 401, and the density of the second oxide semiconductor layer 402 is greater than the density of the first oxide semiconductor layer 401.

Specifically, the material for the gate electrode 20 includes one or more of molybdenum (Mo), aluminum (Al) and copper (Cu).

Specifically, the gate insulation layer 30 is the silicon nitride (SiNₓ) layer, the silicon oxide (SiOₓ) layer, or the lamination composite film of the silicon nitride (SiNₓ) layer and the silicon oxide (SiOₓ) layer.

Specifically, materials for the first oxide semiconductor layer 401 and the second oxide semiconductor layer 402 include one or more of indium gallium zinc oxide (IGZO) and indium zinc tin oxide (IZTO), respectively; the materials for the first oxide semiconductor layer 401 and the second oxide semiconductor layer 402 are the same or different.

Specifically, the density of the first oxide semiconductor layer 401 is less than 6.4 g/cm³, and the density of the second oxide semiconductor layer 402 is greater than 6.4 g/cm³.

Preferably, the thickness of the first oxide semiconductor layer 401 is greater than the thickness of the second oxide semiconductor layer 402, ensuring that the active layer 40 has higher mobility.

Specifically, materials for the drain electrode 51 and the source electrode 52 include one or more of molybdenum (Mo), aluminum (Al), and copper (Cu).

The active layer 40 includes the channel region 41 located between the drain electrode 51 and the source electrode 52, the drain electrode contact region 42 located at one side of the channel region 41 and contacted with the drain electrode 51, and the source electrode contact region 43 located at the other side of the channel region 41 and contacted with the source electrode 52.

The back-channel-etch type oxide semiconductor TFT substrate of the disclosure configures the active layer 40 as a double layer structure, and the first oxide semiconductor layer 401 located in the lower layer has normal density and the second oxide semiconductor layer 402 located in the upper layer has higher density; the first oxide semiconductor layer 401 has lower density and higher mobility and the second oxide semiconductor layer 402 has higher density, fewer numbers of film defects, more strong etch resistance, it is capable of reducing damage of the channel region 41 of the active layer 40 during the process for etching the drain electrode 51 and the source electrode 52; therefore, the active layer 40 of the back-channel-etch type oxide semiconductor TFT substrate has not only higher mobility, but also fewer numbers of film defects, and TFT devices are less affected by light, moisture, oxygen, hydrogen and organics in the environment, thereby having higher reliability.

In summary, the disclosure provides a back-channel-etch type oxide semiconductor TFT substrate and fabricating method thereof. The method for fabricating the back-channel-etch type oxide semiconductor TFT substrate of the disclosure configures an active layer as a double layer structure, and a first oxide semiconductor layer located in a lower layer is prepared according to normal deposition process parameters and has normal density and a second oxide semiconductor layer located in an upper layer is prepared by changing deposition process parameters and has higher density; the first oxide semiconductor layer has lower density and higher mobility and the second oxide semiconductor layer has higher density, fewer numbers of film defects, more strong etch resistance, it is capable of reducing damage of a channel region of an active layer during the process for etching a drain electrode and a source electrode, and at the same time saves a mask for a etch stop layer, cuts down the fabricating cost; therefore, the active layer of the back-channel-etch type oxide semiconductor TFT substrate prepared by the disclosure has not only higher mobility, but also fewer numbers of film defects, and TFT devices are less affected by light, moisture, oxygen, hydrogen and organics in the environment, thereby having higher reliability.

As for the above, various corresponding modifications and alterations may be made by a person skilled in the art according to the technical solution and technical idea of the disclosure, and all these modifications and alterations shall fall within the scope of protection of the claims of the disclosure.

What is claimed is:

1. A method for fabricating a back-channel-etch type oxide semiconductor TFT substrate, comprising:
providing a substrate, depositing and etching a metal material on the substrate to form a gate electrode, and forming a gate insulation layer on the substrate for covering the gate electrode;
depositing a first oxide semiconductor layer on the gate insulation layer, depositing a second oxide semiconductor layer on the first oxide semiconductor layer, and a density of the second oxide semiconductor layer being greater than a density of the first oxide semiconductor layer;
patterning the first oxide semiconductor layer and the second oxide semiconductor layer to obtain an active layer;
depositing and etching a metal material on the active layer and the gate insulation layer to form a drain electrode and a source electrode, and the drain electrode and the source electrode contacting with two sides of the active layer, respectively;
forming a passivation layer on the gate insulation layer for covering the drain electrode, the source electrode and the active layer; forming a through-hole on the passivation layer and corresponding to a part over the drain electrode.

2. The method for fabricating the back-channel-etch type oxide semiconductor TFT substrate according to claim 1, wherein materials for the first oxide semiconductor layer and the second oxide semiconductor layer comprise one or more of indium gallium zinc oxide and indium zinc tin oxide, respectively; the materials for the first oxide semiconductor layer and the second oxide semiconductor layer are the same or different.

3. The method for fabricating the back-channel-etch type oxide semiconductor TFT substrate according to claim 1, wherein the density of the first oxide semiconductor layer is less than 6.4 g/cm³, and the density of the second oxide semiconductor layer is greater than 6.4 g/cm³.

4. The method for fabricating the back-channel-etch type oxide semiconductor TFT substrate according to claim 1, wherein a thickness of the first oxide semiconductor layer is greater than a thickness of the second oxide semiconductor layer.

5. The method for fabricating the back-channel-etch type oxide semiconductor TFT substrate according to claim 1, wherein a material for the gate electrode comprises one or more of molybdenum, aluminum, and copper; the gate insulation layer is a silicon nitride layer, a silicon oxide layer, or a lamination composite film of the silicon nitride layer and the silicon oxide layer; the passivation layer is a silicon nitride layer or a silicon oxide layer; materials for the drain electrode and the source electrode comprise one or more of molybdenum, aluminum, and copper.

6. A back-channel-etch type oxide semiconductor TFT substrate, comprising: a the substrate, a gate electrode disposed on the substrate, a gate insulation layer disposed on the substrate and covering the gate electrode, an active layer disposed on the gate insulation layer and corresponding to a part over the gate electrode, a drain electrode and a source electrode disposed on the active layer and the gate insulation layer and contacted with two sides of the active layer respectively, a passivation layer disposed on the gate insulation layer and covering the drain electrode, the source electrode and the active layer, and a through-hole disposed on the passivation layer and corresponding to the part over the drain electrode;
the active layer comprising a first oxide semiconductor layer disposed on the gate insulation layer and a second oxide semiconductor layer disposed on the first oxide semiconductor layer, and a density of the second oxide semiconductor layer being greater than a density of the first oxide semiconductor layer.

7. The back-channel-etch type oxide semiconductor TFT substrate according to claim 6, wherein materials for the first oxide semiconductor layer and the second oxide semiconductor layer comprise one or more of indium gallium zinc oxide and indium zinc tin oxide, respectively; the materials for the first oxide semiconductor layer and the second oxide semiconductor layer are the same or different.

8. The back-channel-etch type oxide semiconductor TFT substrate according to claim 6, wherein the density of the first oxide semiconductor layer is less than 6.4 g/cm³, and the density of the second oxide semiconductor layer is greater than 6.4 g/cm³.

9. The back-channel-etch type oxide semiconductor TFT substrate according to claim 6, wherein a thickness of the first oxide semiconductor layer is greater than a thickness of the second oxide semiconductor layer.

10. The back-channel-etch type oxide semiconductor TFT substrate according to claim 6, wherein a material for the gate electrode comprises one or more of molybdenum, aluminum, and copper; the gate insulation layer is a silicon nitride layer, a silicon oxide layer, or a lamination composite film of the silicon nitride layer and the silicon oxide layer; the passivation layer is a silicon nitride layer or a silicon oxide layer; materials for the drain electrode and the source electrode comprise one or more of molybdenum, aluminum, and copper.

11. A method for fabricating a back-channel-etch type oxide semiconductor TFT substrate, comprising:
providing a substrate, depositing and etching a metal material on the substrate to form a gate electrode, and forming a gate insulation layer on the substrate for covering the gate electrode;
depositing a first oxide semiconductor layer on the gate insulation layer, depositing a second oxide semiconductor layer on the first oxide semiconductor layer, and a density of the second oxide semiconductor layer being greater a density of the first oxide semiconductor layer;
patterning the first oxide semiconductor layer and the second oxide semiconductor layer to obtain an active layer;
depositing and etching a metal material on the active layer and the gate insulation layer to form a drain electrode and a source electrode, and the drain electrode and the source electrode contacting with two sides of the active layer, respectively;
forming a passivation layer on the gate insulation layer for covering the drain electrode, the source electrode and the active layer; forming a through-hole on the passivation layer and corresponding to a part over the drain electrode;
wherein materials for the first oxide semiconductor layer and the second oxide semiconductor layer comprise one or more of indium gallium zinc oxide and indium zinc tin oxide, respectively; the materials for the first oxide semiconductor layer and the second oxide semiconductor layer are the same or different;
wherein the density of the first oxide semiconductor layer is less than 6.4 g/cm³, and the density of the second oxide semiconductor layer is greater than 6.4 g/cm³;
wherein a thickness of the first oxide semiconductor layer is greater than a thickness of the second oxide semiconductor layer;
wherein a material for the gate electrode comprises one or more of molybdenum, aluminum, and copper; the gate insulation layer is a silicon nitride layer, a silicon oxide layer, or a lamination composite film of the silicon nitride layer and the silicon oxide layer; the passivation layer is a silicon nitride layer or a silicon oxide layer; materials for the drain electrode and the source electrode comprise one or more of molybdenum, aluminum, and copper.
